(19) United States
(12) Patent Application Publication
(10) Pub. No.: US 2022/0225511 A1
(43) Pub. Date: Jul. 14, 2022

(54) RIGID-FLEXIBLE CIRCUIT BOARD WITH EASY AND SIMPLE MANUFACTURE AND METHOD FOR MANUFACTURING THE SAME

(71) Applicants: QING DING PRECISION ELECTRONICS (HUAIAN) CO.,LTD, Huai an (CN); Avary Holding (Shenzhen) Co., Limited., Shenzhen (CN)

(72) Inventor: WEI-XIANG LI, Shenzhen (CN)

(21) Appl. No.: 17/706,011

(22) Filed: Mar. 28, 2022

Related U.S. Application Data
(63) Continuation of application No. PCT/CN2020/086740, filed on Apr. 24, 2020.

(51) Int. Cl. H05K 3/46; H05K 1/02; H05K 1/11

(52) U.S. Cl. CPC H05K 3/4635; H05K 1/028; H05K 3/4614; H05K 1/115; H05K 1/0298

(57) ABSTRACT

A rigid-flexible circuit board which can be simply and easily manufactured includes a wiring substrate, two adhesive layers, and two outer conductive wiring layers. The wiring substrate defines an opening penetrating and splitting the wiring substrate. The two outer conductive wiring layers are stacked on opposite surfaces of the wiring substrate. Each of the two adhesive layers is bonded between one of the two outer conductive wiring layers and the wiring substrate and infills the opening. A simplified method for manufacturing the rigid-flexible circuit board is also disclosed.

### FIELD

The present disclosure relates to a circuit board and a manufacturing method thereof, in particular to a rigid-flexible circuit board and a method for manufacturing the rigid-flexible circuit board.

### BACKGROUND

A rigid-flexible circuit board comprises at least one rigid region and at least one flexible region, allowing durability and flexibility in the circuit board. The rigid-flexible circuit board is suitable for use even with precision electronic products, such as portable electronic products, medical electronic products, and military equipment.

A manufacturing method of the rigid-flexible circuit board can include steps of first, manufacturing a soft wiring substrate; next, laminating a hard wiring substrate on the soft wiring substrate; finally, forming an opening in a predetermined area of the hard wiring substrate, so that part of the soft wiring substrate is exposed from the opening to form a flexible area, while the rest of the soft wiring substrate forms a rigid area together with the hard wiring substrate. The above method is complex and costly.

### BRIEF DESCRIPTION OF THE DRAWINGS

FIG. 1 is a schematic cross-sectional view showing a wiring substrate according to an embodiment of the present disclosure.

FIG. 2 is a schematic cross-sectional view showing a flexible single-sided metal clad laminate according to an embodiment of the present disclosure.

FIG. 3 is a schematic cross-sectional view showing an intermediate structure formed by laminating the wiring substrate of FIG. 1 on the flexible single-sided metal clad laminate of FIG. 2.

FIG. 4 is a schematic cross-sectional view showing a conductive hole and an outer conductive layer formed on the intermediate structure of FIG. 3.

FIG. 5 is a schematic cross-sectional view showing a solder mask layer formed on the outer conductive layer of FIG. 4.

FIG. 6 is a schematic cross-sectional view showing a double-sided copper clad laminate according to an embodiment of the present disclosure.

FIG. 7 is a schematic cross-sectional view showing a first through hole formed on the double-sided copper clad laminate of FIG. 6.

FIG. 8 is a schematic cross-sectional view showing a conductive hole and a conductive layer formed on the double-sided copper clad laminate of FIG. 7.

FIG. 9 is a schematic cross-sectional view showing a wiring substrate according to an embodiment of the present disclosure.

FIG. 10 is a schematic cross-sectional view showing a rigid-flexible circuit board according to an embodiment of the present disclosure.

FIG. 11 is a schematic cross-sectional view showing a rigid-flexible circuit board according to another embodiment of the present disclosure.

### DETAILED DESCRIPTION

The technical solutions in the embodiments of the present disclosure are clearly and completely described in the following with reference to the accompanying drawings in the embodiments of the present disclosure. The described embodiments are only some of the embodiments of the present disclosure, and not all of the embodiments. All other embodiments obtained by those skilled in the art based on the embodiments of the present disclosure without creative efforts are within the scope of the present disclosure.

Unless otherwise defined, all technical and scientific terms used herein have the same meaning as those understood by the common worker in the art. The terminology used in the description of the present disclosure is for the purpose of describing particular embodiments and is not intended to limit the disclosure.

Some embodiments of the present disclosure are described in detail below with reference to the accompanying drawings. The features of the embodiments and examples described below can be combined with each other without conflict.

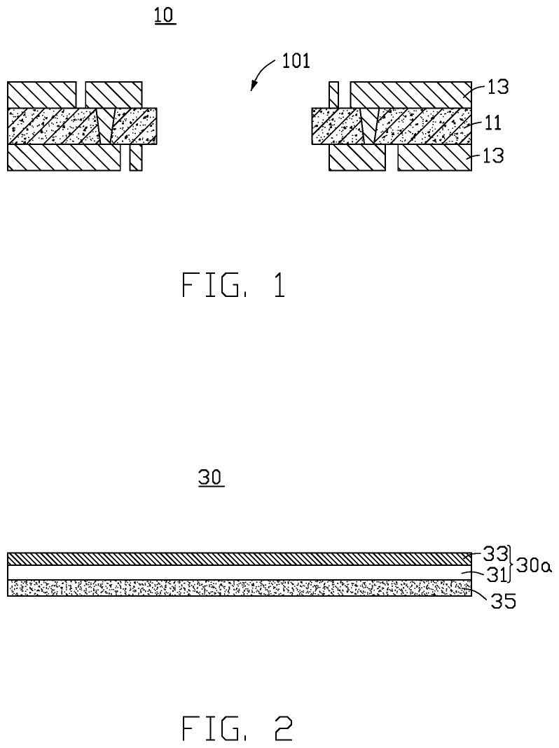

Referring to FIG. 1 to FIG. 4, a method for manufacturing a rigid-flexible circuit board 100 according to an embodiment of the present disclosure includes the following steps:

Step S1, referring to FIG. 1, a wiring substrate 10 is provided, and at least one opening 101 is defined on the wiring substrate 10 to divide the wiring substrate 10, the opening 101 penetrates and completely separates the wiring substrate 10 into two parts.

In the present embodiment, the opening 101 may be formed by, but is not limited to, mechanical drilling, laser drilling, or etching.

In the present embodiment, referring to FIG. 1, the wiring substrate 10 is a double-sided wiring substrate and includes an insulating layer 11 and two inner conductive wiring layers 13 on opposite surfaces of the insulating layer 11. The opening 101 penetrates the insulating layer 11 and the two inner conductive wiring layers 13.

A material of the insulating layer 11 may be one selected from a group consisting of polyimide, teflon, polysulfide, polymethylmethacrylate, polycarbonate, polyethylene terephthalate, polyimide polyethylene terephthalate copolymer, and a combination thereof. The insulating layer 11 may also protrude from an inner wall of the opening 101 relative to the two inner conductive wiring layers 13, so that a step exists between the insulating layer 11 and each of the two inner conductive wiring layers 13 at the opening 101.

Step S2, referring to FIG. 2, two flexible single-sided metal clad laminates 30 are provided. Each of the two flexible single-sided metal clad laminates 30 includes an insulating base layer 31, a first metal layer 33, and an adhesive layer 35. The first metal layer 33 and the adhesive layer 35 are disposed on opposite surfaces of the insulating base layer 31.

In the present embodiment, first, a single-sided copper clad laminate 30a may be provided, the single-sided copper clad laminate 30a includes the insulating base layer 31 and a copper layer as the first metal layer 33 laminated on the insulating base layer 31. Then, the adhesive layer 35 is pasted onto a surface of the insulating base layer 31 away from the copper layer. A material of the adhesive layer 35 may be thermoplastic adhesive, which may be, but is not limited to, one selected from a group consisting of thermoplastic polyimide (TPI), polyetheretherketone, and a combination thereof.

In other embodiments, the adhesive layer 35 may be formed on the surface of the insulating base layer 31 away from the copper layer by coating, spraying, or printing.

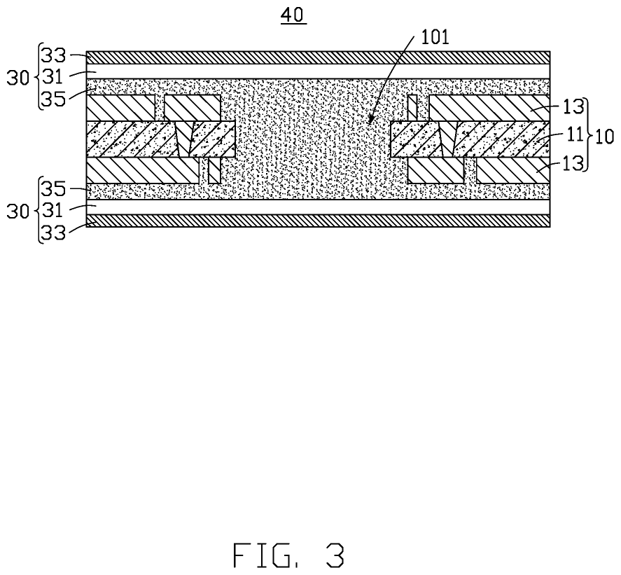

Step S3, referring to FIG. 3, one of the two flexible single-sided metal clad laminates 30, the wiring substrate 10, and another of the two flexible single-sided metal clad laminates 30 are stacked and pressed in that order to form an intermediate structure 40. Each of the two flexible single-sided metal clad laminates 30 is combined with the wiring substrate 10 through the adhesive layer 35. After the pressing, the adhesive layers 35 of the two flexible single-sided metal clad laminates 30 infill the opening 101 and are bonded with each other.

Specifically, an area of each of the two flexible single-sided metal clad laminates 30 corresponding to the opening 101 may be concave towards the opening 101 and closely combined with the inner wall of the opening 101.

In the present embodiment, before the pressing, the two flexible single-sided metal clad laminates 30 are pasted on the two inner conductive wiring layers 13 through the adhesive layers 35.

When pressing, the adhesive layers 35 are heated to decrease viscosity, so that the adhesive layers 35 flow into and infill a gap between the wiring substrate 10 and the insulating base layer 31 and the opening 101, and the two flexible single-sided metal clad laminates 30 are thereby closely combined with the wiring substrate 10. Since the insulating layer 11 protrudes from the inner wall of the opening 101 relative to the two inner conductive wiring layers 13, adhesion between the adhesive layers 35 and the opening 101 is improved.

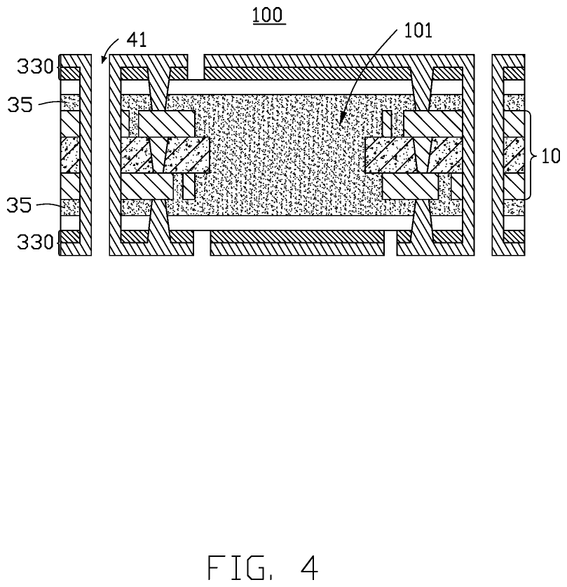

Step S4, referring to FIG. 4, at least one first conductive hole 41 is formed on the intermediate structure 40 to electrically connect the first metal layers 33 of the two flexible single-sided metal clad laminates 30 with the wiring substrate 10, and two outer conductive wiring layers 330 are formed from the first metal layers 33.

The manufacturing method of the rigid-flexible circuit board 100 is simple and easy to operate. The area corresponding to the opening 101 of the rigid-flexible circuit board 100 will become the flexible area of the rigid-flexible circuit board 100. The usual commencing step of forming the flexible area is omitted in this manufacturing method, which simplifies the manufacturing process and avoids damage or pollution to the circuit board in the commencing step.

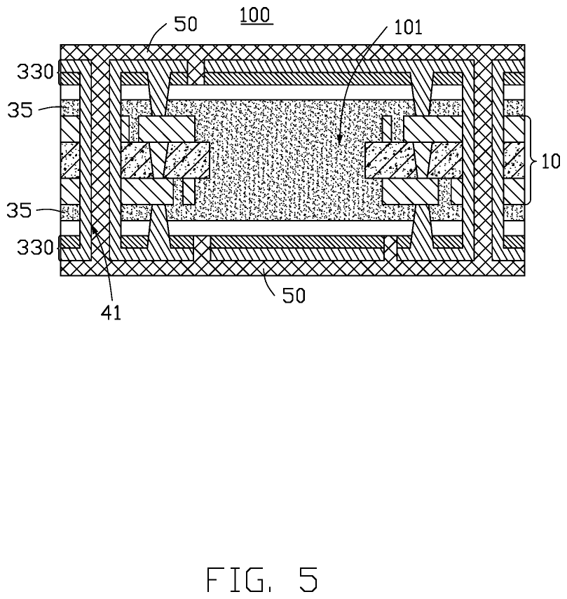

In some embodiments, after the step S4, the method may also include step S5. Referring to FIG. 5, two solder mask layers 50 are formed on surfaces of the two outer conductive wiring layers 330 away from the wiring substrate 10, the two solder mask layers 50 infill gaps in the two outer conductive wiring layers 330 and the first conductive hole 41.

In the present embodiment, the wiring substrate 10 is manufactured as follows:

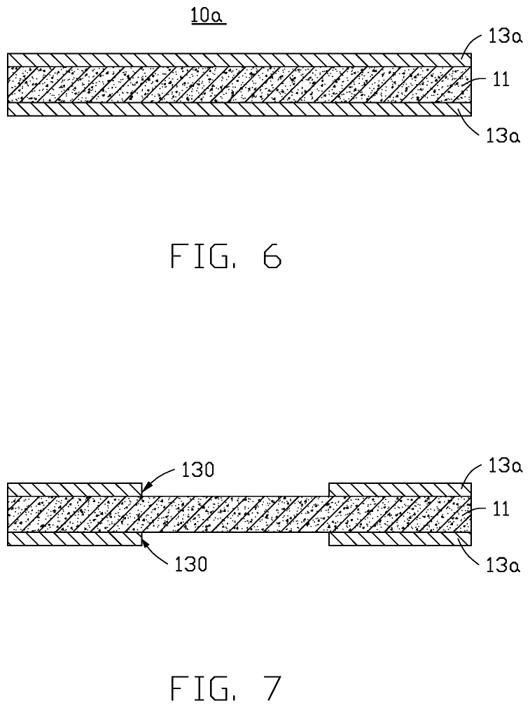

Step one, referring to FIG. 6, a double-sided copper clad laminate 10a is provided. The double-sided copper clad laminate 10a includes the insulating layer 11 and two base copper layers 13a on opposite surfaces of the insulating layer 11.

Step two, referring to FIG. 7, two first through holes 130 are formed on the two base copper layers 13a of the double-sided copper clad laminate 10a to expose part of the insulating layer 11. The two first through holes 130 on the two base copper layers 13a are opposite to each other.

In the present embodiment, the first through holes 130 are formed by mechanical drilling.

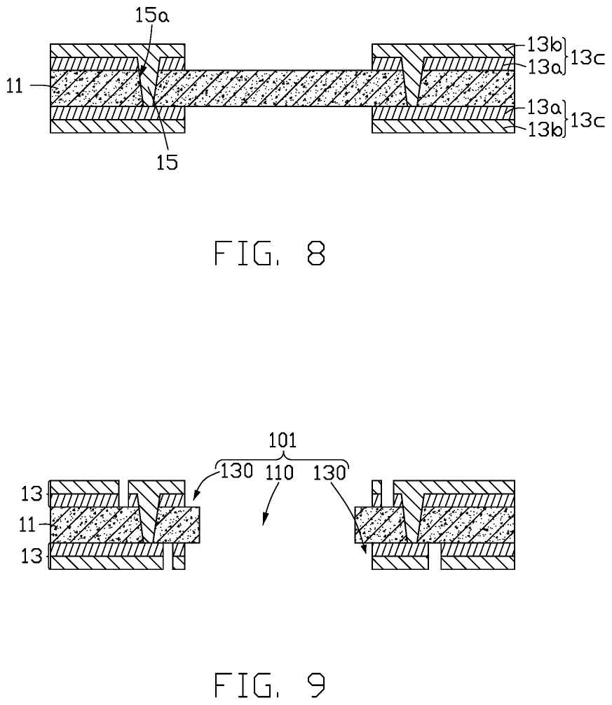

Step three, referring to FIG. 8, two second conductive holes 15 adjacent to opposite sides of the first through hole 130 are formed to electrically connect the two base copper layers 13a, and a conductive layer 13b is deposited on each of the two base copper layers 13a. A second metal layer 13c is constituted by one base copper layer 13a and one conductive layer 13b stacked on the one base copper layer 13a.

Specifically, two communication holes 15a which penetrate each second metal layer 13c and also the insulating layer 11 are formed on the double-sided copper clad laminate 10a by laser, residue of resin in the communication holes 15a is removed, the two communication holes 15a are electroplated to form the two second conductive holes 15, and two conductive layers 13b are deposited on the two base copper layers 13a respectively by electroplating.

Step four, referring to FIG. 9, each of the two inner conductive wiring layers 13 is formed from one second metal layer 13c, and a second through hole 110 is formed on the insulating layer 11 at a position corresponding to the two first through holes 130. The second through hole 110 communicates with the two first through holes 130. The second through hole 110 and the two first through holes 130 constitute the opening 101.

In the present embodiment, a size of the second through hole 110 is smaller than a size of each of the two first through holes 130, so that the insulating layer 11 protrudes out of the two inner conductive wiring layers 13 towards a central axis of the opening 101. This avoids damage of the two inner conductive wiring layers 13 when the second through hole 110 is formed.

Specifically, in some embodiments, the two second metal layers 13c may also be thinned before the two inner conductive wiring layers 13 are formed.

In other embodiments, the wiring substrate 10 may be manufactured by other methods. In other embodiments, the wiring substrate 10 may be a multi-layer wiring substrate, which is formed by a build-up method on above double-layer wiring substrate.

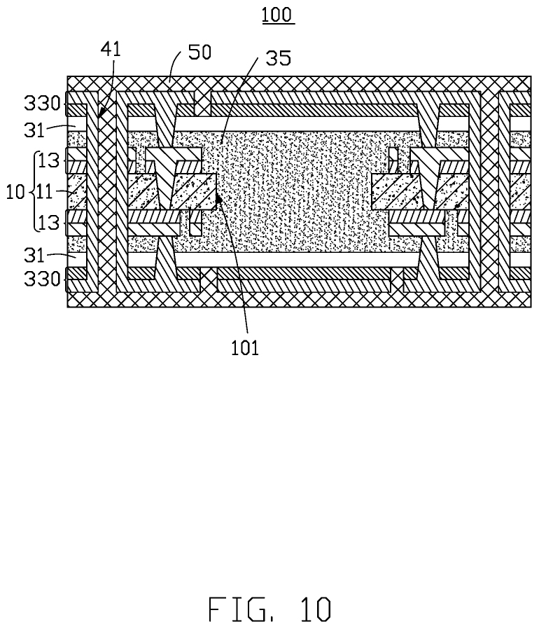

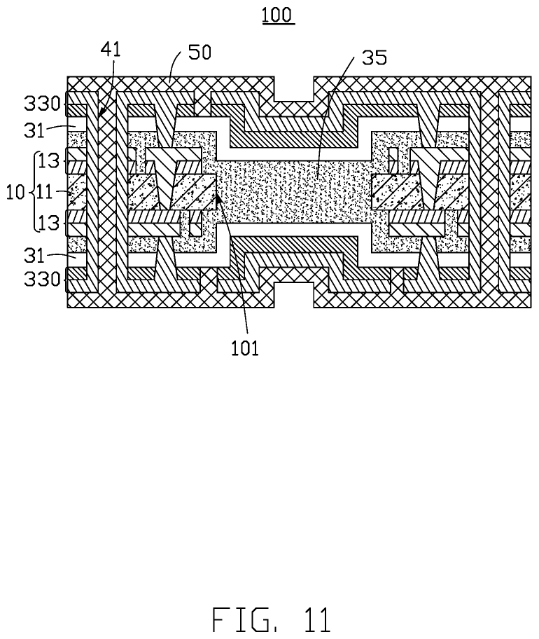

Referring to FIG. 10, an embodiment of the rigid-flexible circuit board 100 is provided. The rigid-flexible circuit board 100 includes the wiring substrate 10, the two adhesive layers 35, and the two outer conductive wiring layers 330. The wiring substrate 10 defines at least one opening 101 penetrating the wiring substrate 10 to divide the wiring substrate 10 and separate the same in two. The two outer conductive wiring layers 330 are stacked on opposite surfaces of the wiring substrate 10, each of the two adhesive layers 35 is bonded between one of the two outer conductive wiring layers 330 and the wiring substrate 10, and the adhesive layers 35 infill the opening 101. An area of the rigid-flexible circuit board 100 corresponding to the opening 101 becomes a flexible region, while other areas of the rigid-flexible circuit board 100 remain as rigid regions.

Specifically, referring to FIG. 11, an area of each of the two outer conductive wiring layers 330 corresponding to the opening 101 is concave towards the opening 101, to be closely combined with the inner wall of the opening 101.

The wiring substrate 10 may be a double-sided wiring substrate or a multi-layer wiring substrate. In the present embodiment, the wiring substrate 10 is a double-sided wiring substrate and includes the insulating layer 11 and two inner conductive wiring layers 13 bonded to opposite surfaces of the insulating layer 11. The opening 101 splits the insulating layer 11 and the two inner conductive wiring layers 13. In the present embodiment, the insulating layer 11 may also protrude from the inner wall of the opening 101 relative to the two inner conductive wiring layers 13.

The material of the insulating layer 11 may be one selected from a group consisting of polyimide, teflon, polysulfide, polymethylmethacrylate, polycarbonate, polyethylene terephthalate, polyimide polyethylene terephthalate copolymer, and a combination thereof.

The material of the adhesive layer 35 may be thermoplastic adhesive, which may be, but is not limited to, one selected from a group consisting of thermoplastic polyimide (TPI), polyetheretherketone, and a combination thereof.

The rigid-flexible circuit board 100 also includes the first conductive hole 41 electrically connecting the wiring substrate 10 with the two outer conductive wiring layers 330.

The rigid-flexible circuit board 100 also includes two insulating base layers 31. Each of the two insulating base layers 31 is located between one of the two adhesive layers 35 and one of the two outer conductive wiring layers 330.

The rigid-flexible circuit board 100 also includes the two solder mask layers 50 disposed on surfaces of the two outer conductive wiring layers 330 away from the wiring substrate 10. The two solder mask layers 50 may also infill the first conductive hole 41.

The above is only a preferred embodiment of the present disclosure, and is not intended to limit the scope of the present disclosure. Although embodiments of the present disclosure are described above, it is not intended to limit the present disclosure. The present disclosure may be modified or modified to equivalent variations without departing from the technical scope of the present disclosure by any person skilled in the art. Any simple modifications, equivalent changes and modifications made to the above embodiments remain within the scope of the technical solutions of the present disclosure.

What is claimed is:

1. A method for manufacturing a rigid-flexible circuit board, comprising:
providing a wiring substrate and defining an opening penetrating the wiring substrate;
providing two flexible single-sided metal clad laminates, each of the two flexible single-sided metal clad laminates comprising a first metal layer, an insulating base layer, and an adhesive layer stacked in sequence;
laminating and pressing one of the two flexible single-sided metal clad laminates, the wiring substrate, and another of the two flexible single-sided metal clad laminates in this order along a penetrating direction of the opening to form an intermediate structure, wherein each of the two flexible single-sided metal clad laminates is combined with the wiring substrate through the adhesive layer, and the adhesive layers of the two flexible single-sided metal clad laminates infill the opening and are bonded with each other; and
forming a first conductive hole on the intermediate structure to electrically connect the first metal layers of the two flexible single-sided metal clad laminates with the wiring substrate, and forming two outer conductive wiring layers from the first metal layers.

2. The method of claim 1, wherein the wiring substrate is a double-sided wiring substrate or a multi-layer wiring substrate.

3. The method of claim 2, wherein the wiring substrate comprises an insulating layer and two inner conductive wiring layers disposed on opposite surfaces of the insulating layer, the opening penetrates the insulating layer and the two inner conductive wiring layers, and the insulating layer protrudes from an inner wall of the opening relative to the two inner conductive wiring layers.

4. The method of claim 3, wherein the wiring substrate further comprises a second conductive hole electrically connecting the two inner conductive wiring layers.

5. The method of claim 4, wherein providing a wiring substrate and defining an opening penetrating the wiring substrate comprises:
providing a double-sided copper clad laminate comprising the insulating layer and two base copper layers disposed on the opposite surfaces of the insulating layer;
forming two first through holes on the two base copper layers to expose part of the insulating layer;
forming the second conductive hole electrically connecting the two base copper layers and depositing two conductive layers on the two base copper layers, one of the two base copper layers and one of the two conductive layers constituting a second metal layer;
forming the two inner conductive wiring layers from the second metal layers and forming a second through hole on the insulating layer, the second through hole communicating with the two first through holes, the second through hole and the two first through holes constituting the opening.

6. The method of claim 5, wherein a size of the second through hole is smaller than a size of each of the two first through holes, so that the insulating layer protrudes from the inner wall of the opening relative to the two inner conductive wiring layers.

7. The method of claim 3, wherein a material of the insulating layer is selected from a group consisting of polyimide, teflon, polysulfide, polymethylmethacrylate, polycarbonate, polyethylene terephthalate, polyimide polyethylene terephthalate copolymer, and a combination thereof.

8. The method of claim 1, wherein an area of the first metal layer corresponding to the opening is concave towards the opening.

9. The method of claim 1, further comprising: forming two solder mask layers on surfaces of the two outer conductive wiring layers away from the wiring substrate, each of the two solder mask layers infilling gaps in one of the two outer conductive wiring layers and the first conductive hole.

10. The method of claim 1, wherein a material of the adhesive layer is selected from a group consisting of hermoplastic polyimide, polyetheretherketone, and a combination thereof.

11. A rigid-flexible circuit board comprising:
a wiring substrate defining an opening penetrating the wiring substrate;
two outer conductive wiring layers stacked on opposite surfaces of the wiring substrate along a penetrating direction of the opening; and
two adhesive layers, wherein each of the two adhesive layers is bonded between one of the two outer conductive wiring layers and the wiring substrate and infills the opening.

12. The rigid-flexible circuit board of claim 11, wherein the wiring substrate is a double-sided wiring substrate or a multi-layer wiring substrate.

13. The rigid-flexible circuit board of claim 12, wherein the wiring substrate comprises an insulating layer and two inner conductive wiring layers disposed on opposite surfaces of the insulating layer, the opening penetrates the insulating layer and the two inner conductive wiring layers, and the insulating layer protrudes from an inner wall of the opening relative to the two inner conductive wiring layers.

14. The rigid-flexible circuit board of claim 13, wherein the wiring substrate further comprises a second conductive hole electrically connecting the two inner conductive wiring layers.

15. The rigid-flexible circuit board of claim 13, wherein a material of the insulating layer is selected from a group consisting of polyimide, teflon, polysulfide, polymethylmethacrylate, polycarbonate, polyethylene terephthalate, polyimide polyethylene terephthalate copolymer, and a combination thereof.

16. The rigid-flexible circuit board of claim 11, wherein an area of each of the two outer conductive wiring layers corresponding to the opening is concave towards the opening.

17. The rigid-flexible circuit board of claim 11, further comprising a first conductive hole electrically connecting the two outer conductive wiring layers with the wiring substrate.

18. The rigid-flexible circuit board of claim 17, further comprising two soler mask layers disposed on surfaces of the two outer conductive wiring layers away from the wiring substrate, wherein each of the two solder mask layers infills gaps in one of the two outer conductive wiring layers and the first conductive hole.
